(19) United States
(12) Patent Application Publication
(10) Pub. No.: US 2018/0155500 A1
(43) Pub. Date: Jun. 7, 2018

(54) ELECTRONICS BACKPLANES USING THIOL-CLICK CHEMISTRY SUBSTRATES

(71) Applicant: Board of Regents, The University of Texas System, Austin, TX (US)

(72) Inventors: Radu Reit, Plano, TX (US); Adrian E. Avendano-Bolivar, Richardson, TX (US); David E. Arreaga-Salas, Dallas, TX (US); Walter E. Voit, Dallas, TX (US)

(21) Appl. No.: 15/521,521

(22) PCT Filed: Aug. 16, 2016
(86) PCT No.: PCT/US16/47161

§ 371 Date: Apr. 24, 2017

Related U.S. Application Data
(60) Provisional application No. 62/209,652, filed on Aug. 25, 2015.

(51) Int. Cl. C08G 75/12; H01L 23/498; H01L 51/00

(52) U.S. Cl. CPC C08G 75/12; H01L 23/4985; H01L 29/247; H01L 51/004; H01L 51/0097

(57) ABSTRACT

Novel and advantageous backplanes, which include a thermoset polymer substrate, are provided. The substrate can be flexible, and the polymer of the substrate can be made by mixing multifunctional thiol monomers and specifically chosen co-monomers. The monomers and co-monomers can undergo a thiol “click” chemistry reaction to form a low-cure-stress polymer network that can be used as the substrate for an electronics backplane.

### CROSS-REFERENCE TO RELATED APPLICATION

This application claims the benefit of U.S. Provisional Application Ser. No. 62/209,652, filed Aug. 25, 2015, which is incorporated herein by reference in its entirety, including any figures, tables, and drawings.

### GOVERNMENT SUPPORT

This invention was made with government support under contract award number DGE-1147385/37355012, awarded by the NSF. The government has certain rights in the invention.

### BACKGROUND

Fabrication of flexible backplanes for electronics includes several challenges, due at least in part to the photolithographic processes that the substrate of the backplane must withstand. Even at temperatures below transition and phase-change temperatures, existing backplane substrates do not allow for reliable and reproducible alignment over subsequent photolithographic steps requiring thermal cycling or cycling of other environmental stimuli. In addition, creep, fatigue, and micro-to-macro-scale network rearrangement cause problems for existing backplane substrates and render them inadequate at higher temperatures, such as those often required for formation of additional backplane structures on the substrate or further electronics structures on the backplane. Current flexible electronics backplane materials, such as biaxially-oriented polyethylene naphthalate, polycarbonate, and polyimides, suffer from the inability to align multiple masks over thermal cycling, which limits processing temperatures, size, and/or complexity of electronic structures.

### BRIEF SUMMARY

The subject invention provides novel and advantageous backplanes, as well as methods for fabricating the same and methods for using the same. A backplane of one or more exemplary embodiments can be an electronic backplane and can used for, e.g., the control of light emitting diodes (LEDs), liquid crystals, electrophoretic particles, energy harvesters, and elements sensitive to radiation, pressure and/or temperature. The backplane can include a substrate that includes or is a polymer. The substrate can be flexible. The polymer can be made by mixing of multifunctional thiol monomers and specifically chosen co-monomers. That is, the polymer can be composed of multifunctional thiol monomers and specifically chosen co-monomers, which react to form the resulting polymer. The backplane can include different thin film layers, which can include but are not limited to patterned or otherwise geometrically-defined conductive materials, thin film dielectrics, and semiconductors.

While conventional approaches to fabricate electronic backplanes on polymer substrates yield multi-layer stacks with significant misalignment across layers when exposed to thermal cycles, the backplanes and methods of manufacture described herein surprisingly lead to backplanes with significant dimensional stability (i.e., no significant misalignment). That is, resulting traces do not deviate by more than a predetermined amount (e.g., 4 per cm away from a predetermined reference point, such as a center point for lithography steps). This can be referred to as the backplane or the substrate having dimensional stability. These traces may not deviate by more than a predetermined amount (e.g., 4 μm per cm) even after multiple thermal cycles (e.g., five thermal cycles to 250° C.). The reference point to determine deviation or misalignment can be determined by the defined geometries dictated by shadow, photolithographic, and/or other mask(s). Related art backplanes including polymer substrates, which can also include thin film conductors, dielectrics, and semiconductors, cannot be fabricated within these tolerances, and this limitation has limited large scale adoption of large are, low cost backplanes.

In an embodiment, a backplane can include a substrate including a thermoset polymer, and the thermoset polymer can be prepared by curing a pre-thermoset mixture. The pre-thermoset mixture can include from about 25 wt % to about 65 wt % of one or more multifunctional thiol monomers and from about 25 wt % to about 65 wt % of one or more multifunctional co-monomers. In a further embodiment, the pre-thermoset mixture can further include from about 0.001 wt % to about 10 wt % of small molecule additives. In yet a further embodiment, the pre-thermoset mixture can include from about 0.1 wt % to about 10 wt % of small molecule additives.

In another embodiment, a method of fabricating a backplane can include: preparing a pre-thermoset mixture; and curing the pre-thermoset mixture to form a thermoset polymer as a substrate of the backplane. The pre-thermoset mixture can include from about 25 wt % to about 65 wt % of one or more multifunctional thiol monomers and from about 25 wt % to about 65 wt % of one or more multifunctional co-monomers. In a further embodiment, the pre-thermoset mixture can further include from about 0.001 wt % to about 10 wt % of small molecule additives. In yet a further embodiment, the pre-thermoset mixture can include from about 0.1 wt % to about 10 wt % of small molecule additives.

### BRIEF DESCRIPTION OF THE DRAWINGS

The following figures are included to illustrate certain aspects of the present disclosure and should not be viewed as exclusive embodiments. The subject matter disclosed is capable of considerable modifications, alterations, combinations, and equivalents in form and function, without departing from the scope of this disclosure.

FIG. 1 shows a cross-sectional schematic diagram of a backplane according to an exemplary embodiment.

FIG. 2 shows a cross-sectional schematic diagram of a backplane according to an exemplary embodiment.

FIG. 3 shows a flow diagram of a method of fabricating a backplane according to an exemplary embodiment.

### DETAILED DESCRIPTION

In the following detailed description of the illustrative embodiments, reference is made to the accompanying drawings that form a part thereof and is provided to assist the reader in gaining a comprehensive understanding of the methods, apparatuses, and/or systems described herein. These embodiments are described in sufficient detail to enable those skilled in the art to practice the invention, and it is understood that other embodiments may be utilized and that logical structural, mechanical, electrical, and chemical changes may be made without departing from the spirit or scope of the invention. Accordingly, various changes, modifications, and equivalents of the methods, apparatuses, and/or systems described herein will be suggested to those of ordinary skill in the art. The progression of processing operations described is an example; however, any sequence is not necessarily limited to that set forth herein and may be changed as is known in the art, with the exception of operations necessarily occurring in a particular order.

To avoid detail not necessary to enable those skilled in the art to practice the embodiments described herein, the description may omit certain information known to those skilled in the art. Also, the respective descriptions of well-known functions and constructions may be omitted for increased clarity and conciseness. The following detailed description is, therefore, not to be taken in a limiting sense. Illustrative embodiments are presented in the appended claims.

Additionally, exemplary embodiments will now be described more fully hereinafter with reference to the accompanying drawings. The exemplary embodiments may, however, be embodied in many different forms and should not be construed as being limited to the embodiments set forth herein. These embodiments are provided so that this disclosure will be thorough and complete and will fully convey the exemplary embodiments to those of ordinary skill in the art. Like numerals denote like elements throughout.

Unless otherwise specified, any use of any form of the terms “connect”, “engage”, “couple”, “attach”, or any other term describing an interaction between elements is not meant to limit the interaction to direct interaction between the elements and may also include indirect interaction between the elements described. In the following discussion and in the claims, the terms “including” and “comprising” are used in an open-ended fashion and thus should be interpreted to mean “including, but not limited to.” Unless otherwise indicated, as used throughout this document, “or” does not require mutual exclusivity.

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

When the term “about” is used herein, in conjunction with a numerical value, it is understood that the value can be in a range of 95% of the value to 105% of the value, i.e. the value can be +/−5% of the stated value. For example, “about 1 kg” means from 0.95 kg to 1.05 kg.

Novel and advantageous backplanes are provided, as well as methods for fabricating the same and methods for using the same. A backplane according to one or more embodiments can be an electronic backplane and can used for, e.g., the control of light emitting diodes (LEDs), liquid crystals, electrophoretic particles, energy harvesters, and elements sensitive to radiation, pressure and/or temperature. The backplane can include a substrate that includes or is a polymer. The substrate can be flexible. The polymer can be made by mixing of multifunctional thiol monomers and specifically chosen co-monomers. In the production of the polymer, the multifunctional thiol monomers and specifically chosen co-monomers can be mixed to form a resin, and the resin can be injected into a reservoir (e.g., a pressurized reservoir). Uniform sheet production can be performed on the resin, and the uniform sheet production can be performed via, for example, slot die coating, rod coating, blade coating, spin coating, and/or reaction injection molding, though embodiments are not limited thereto.

In many embodiments, one or more additional structures can be formed on a substrate to create a backplane. Such additional structures can include, but are not limited to, semiconductors (e.g., amorphous oxide semiconductors such as indium gallium zinc oxide (IGZO)), diodes, transistors, capacitors, and resistors. In certain embodiments, one or more photolithographic steps can be performed on the finished substrate to form additional structures, such as those mentioned, of the backplane on the substrate. The additional structures can enable the backplane to be suitable for complex electronics.

Monomer combinations used for the substrate of the backplanes can enable synthesis of a thermoset polymer with a cure stress that is low, and can be zero or close to zero. The resulting polymer can then be used for a substrate for a backplane (e.g., an electronic backplane). The substrate can include a glass panel or a wafer (e.g., a silicon wafer) with the polymer disposed thereon. Alternatively, the substrate can be the polymer. The polymer can be a low-cure-stress and thermoset network that limits creep, limits fatigue, and limits micro-to-macro-scale network rearrangement. This can be accomplished by using the materials and proportions thereof as described herein. These problems (creep, fatigue, and micro-to-macro-scale network rearrangement) plague related art backplane substrates and render them inadequate at higher temperatures, such as those often required for formation of additional backplane structures on the substrate or further electronics structures on the backplane.

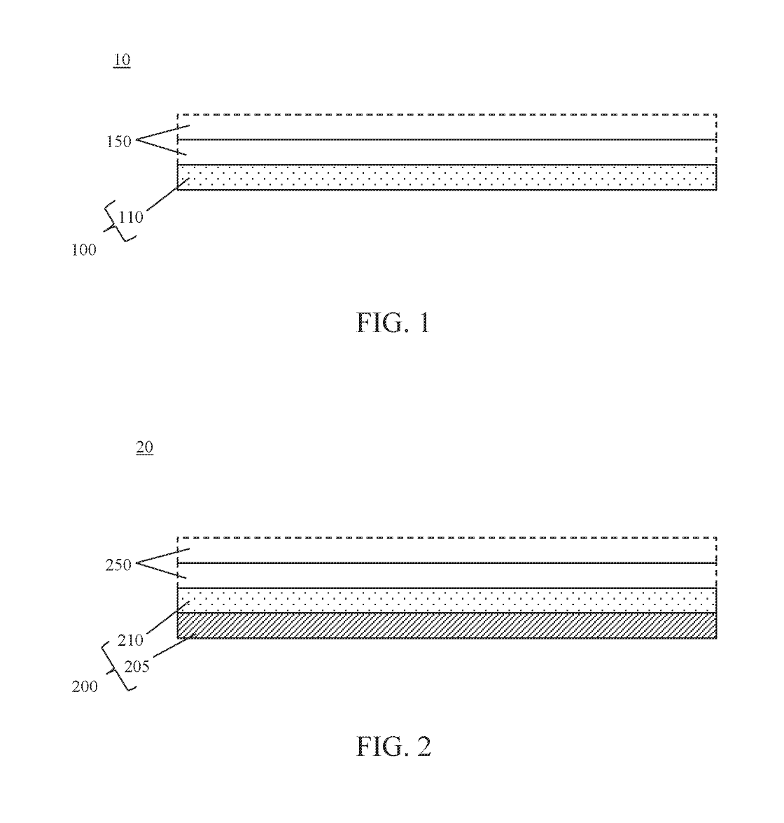

FIG. 1 shows a cross-sectional diagram of a backplane according to one embodiment of the subject invention. Referring to FIG. 1, the backplane 10 can include a substrate 100, which can be a polymer 110 as described herein. One or more additional structures 150 can be formed on the substrate 100. The additional structures 150 are represented by dashed-line boxes because they can take many different forms depending on the application of the backplane 10. The additional structures 200 need not cover the entire substrate 100 and can be any number of layers, including one.

FIG. 2 shows a cross-sectional diagram of a backplane according to one embodiment of the subject invention. Referring to FIG. 2, the backplane 20 can include a substrate 200, which can include a base substrate 205 and a polymer 210 as described herein disposed on the base substrate 205. The base substrate 205 can be, for example, a glass panel or a wafer (e.g., a silicon wafer). One or more additional structures 250 can be formed on the substrate 200. The additional structures 250 are represented by dashed-line boxes because they can take many different forms depending on the application of the backplane 20. The additional structures 250 need not cover the entire substrate 200 and can be any number of layers, including one. In an alternative embodiment, the position of the base substrate 205 and the polymer 210 can be switched.

According to another embodiment, a plurality of alternating layers of a substrate and a polymer can be provided. Further, additional structures can be provided between any of the plurality of alternating layers. For example, a display component that includes a substrate, a polymer layer on the substrate, and one or more additional structures on the polymer layer can be provided along with a touch input component disposed on the display component. The touch input component can include another substrate, polymer layer, and additional structures, including, for example, an insulating layer and/or input circuit layers.

Polymers and polymer systems according to the subject invention have the unique ability to be processed effectively at temperatures higher than their glass transition temperature. This is due at least in part to the nature of the network bonding (e.g., a thermoset, covalently-linked network that inhibits or prevents chain drift), resulting in dimensional stability of the material when it is above said glass transition temperature. This property limits shrinking, warping, and the evolution of surface imperfections that typically preclude flexible substrates from being used at temperatures above their glass transition temperature. The ability of the polymers and polymer systems to be processed effectively at temperatures higher than their glass transition temperature may also be due in part to low cure-stress, which inhibits or prevents evolution of surface roughness through the glass transition.

In many embodiments, a polymer used for a substrate can be a thiol, click-based thermoset polymer. For example, combinations of properly-chosen difunctional thiols and difunctional alkenes can be used to create click-based thermoplastics that can be advantageous for use in thermoplastic processing. These thermoplastic polymers can more readily allow for roll-to-roll processing due to the low cure stress (possibly as low as zero), though it is important to note that other advantages result from polymers of the subject invention.

The polymer of the substrate of the backplane can be the result of a “click” chemistry reaction between one or more first multifunctional monomers and one or more second multifunctional monomers. In many embodiments, the first multifunctional monomers can be, for example, multifunctional thiol monomers such that the “click” chemistry reaction is a thiol click chemistry reaction. The second multifunctional monomers can be thought of as “co-monomers” and can be chosen from a wide range of functionalities that are compatible with a thiol monomer to result in the thiol click chemistry reaction taking place. In some embodiments, one or more small molecule additives may also be included when a polymerization reaction takes place.

The polymer of the substrate of the backplane can be prepared by curing a pre-thermoset mixture. The mixture can include amount of one or more first multifunctional monomers and one or more second multifunctional monomers. One or more small molecule additives may also be included in the pre-thermoset mixture, though these may be omitted. The first multifunctional monomers can be, for example, multifunctional thiol monomers. The multifunctional thiol monomers can be used in one or more of the following reactions, though embodiments are not limited thereto: thiol-ene, thiol-acrylate, thiol-methacrylate, thiol-epoxy, thiol-maleimide, thiol-isocyanate and thiol-norbornene. These thiol reactions, which are provided by way of example, allow for “click” chemistry reactions (i.e., a thiol click chemistry reaction) with the one or more second multifunctional monomers (e.g., epoxy), which can be considered as co-monomers. The multifunctional co-monomers can be chosen from a wide range of functionalities that are compatible with a thiol monomer to result in the thiol click chemistry reaction taking place.

The pre-thermoset mixture can include a proportion of the one or more first multifunctional monomers of, for example, any of the following values, about any of the following values, at least any of the following values, at least about any of the following values, not more than any of the following values, not more than about any of the following values, or within any range having any of the following values as endpoints (with or without “about” in front of one or both of the endpoints), though embodiments are not limited thereto (all numerical values are in percentage by weight (wt %)): 5, 10, 15, 20, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 70, 75, 80, 85, 90, or 95. For example, the pre-thermoset mixture can include a proportion of the one or more first multifunctional monomers (e.g., multifunctional thiol monomers) from about 25 wt % to about 65 wt % or from 25 wt % to 65 wt %.

The pre-thermoset mixture can include a proportion of the one or more second multifunctional monomers (e.g., multifunctional co-monomers) of, for example, any of the following values, about any of the following values, at least any of the following values, at least about any of the following values, not more than any of the following values, not more than about any of the following values, or within any range having any of the following values as endpoints (with or without “about” in front of one or both of the endpoints), though embodiments are not limited thereto (all numerical values are in percentage by weight (wt %)): 5, 10, 15, 20, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 70, 75, 80, 85, 90, or 95. For example, the pre-thermoset mixture can include a proportion of the one or more second multifunctional monomers (e.g., multifunctional co-monomers) from about 25 wt % to about 65 wt % or from 25 wt % to 65 wt %.

The pre-thermoset mixture can include a proportion of the one or more small molecule additives of, for example, any of the following values, about any of the following values, at least any of the following values, at least about any of the following values, not more than any of the following values, not more than about any of the following values, or within any range having any of the following values as endpoints (with or without “about” in front of one or both of the endpoints), though embodiments are not limited thereto (all numerical values are in percentage by weight (wt %)): 0, 0.1, 0.2, 0.3, 0.4, 0.5, 0.6, 0.7, 0.8, 0.9, 1, 2, 3, 4, 5, 6, 7, 8, 9, 10, 11, 12, 13, 14, 15, 20, 25, or 30. For example, the pre-thermoset mixture can include a proportion of the one or more small molecule additives of from about 0.1 wt % to about 10 wt % or from 0.1 wt % to 10 wt %.

Careful selection of the first and second multifunctional monomers can result in a highly tunable system, where the glass transition (Tg), the dissociation temperature (Td), and/or the rubbery modulus (Gr) of the system can be independently adjusted. The following are non-limiting examples of ways to alter the Tg: using higher functionality (e.g., tetrafunctional instead of trifunctional, etc.) thiol monomers or higher functionality co-monomers while maintaining the functionality of the other component can increase the Tg; using lower functionality thiol monomers or lower functionality co-monomers while maintaining the functionality of the other component can decrease the Tg; using more rigid (e.g., linear instead of cyclic) linkages for either component can increase the Tg; using less rigid linkages for either component can decrease the Tg; using a more rotationally-confined linkage between monomers (e.g., succinimide thioether (C—S-Succinimide) instead of thioether (C—S—C)) can increase the Tg; and using a less rotationally-confined linkage between monomers can decrease the Tg. The following are non-limiting examples of ways to alter the Gr: using higher functionality thiol monomers or higher functionality co-monomers while maintaining the functionality of the other component can increase the Gr; using lower functionality thiol monomers or lower functionality co-monomers while maintaining the functionality of the other component can decrease the Gr; using a polymer with increased free volume between chains (e.g., due to porosity or space-sweeping side-chains) can decrease the Gr; and using a polymer with decreased free volume between chains can increase the Gr. The following are non-limiting examples of ways to alter the Td, which can be more difficult than altering the Tg and/or Gr in systems of the subject invention: using higher functionality thiol monomers or higher functionality co-monomers while maintaining the functionality of the other component can increase the Td; using lower functionality thiol monomers or lower functionality co-monomers while maintaining the functionality of the other component can decrease the Td; using monomers with increased availability of supramolecular interactions (e.g., hydrogen bonding or Pi-Pi stacking) can increase the Td; and using monomers with decreased availability of supramolecular interactions can decrease the Td. All of the examples given for altering the Tg, Gr, or Td can be performed such that only the change listed in the example is performed, thereby enabling independent control of these properties.

The polymer of the substrate of the backplane can be a thermoset network (a covalently cross-linked system) that shows increased dimensional stability past transitions like the Tg or the melt temperature (Tm), resulting in backplane substrates with the ability to be used as flexible substrates for electronic components.

In one embodiment, the polymer of the substrate of the backplane can be a thiol-click thermoset polymer prepared by curing a pre-thermoset mixture, and the mixture can include: from about 25 wt % to about 65 wt % of one or more multifunctional thiol monomers; from about 25 wt % to about 65 wt % of one or more multifunctional co-monomers; and from about 0.1 wt % to about 10 wt % of small molecule additives. The resulting polymer can have a substrate drift of less than 3.5 μm/cm at a temperature of at least 275° C., though embodiments are not limited thereto.

A backplane according to many embodiments of the subject invention can include at least one substrate or substrate layer, at least one conducting layer, and at least one semiconducting layer. A backplane can also optionally include at least one encapsulating layer, at least one dielectric layer, and other layers for a variety of purposes. In many embodiments, a polymer-based backplane includes at least one layer, for example the bottom layer (e.g., a substrate or a substrate layer), is a polymer substrate.

A flexible backplane can be defined as a backplane that can tolerate a specific bending radius of curvature and not alter its as-measured electrical properties by more than 5% after 100 mechanical cycles to that radius of curvature. Typical radii of curvature for flexible inorganic backplanes, such as those made on thinned silicon, can be on the order of 1 cm, while radii of curvature for some polymer substrates could be less than 50 μm. Unless otherwise specifically indicated, flexible electronic backplanes described herein will refer to flexible backplanes including a polymer substrate and not a thinned glass substrate, thinned silicon substrate, thinned InGaS substrate, or other thin inorganic or graphitic substrate. Some polymer-based backplanes not flexible at all, and some polymer-based backplanes are not flexible at one temperature, but may be flexible at another temperature.

In many embodiments, a backplane can have dimensional stability, as defined via “substrate drift.” That is, resulting traces formed on a backplane or a substrate of a backplane will not deviate by more than a predetermined amount (e.g., 4 per cm away from a predetermined reference point, such as a center point for lithography steps). These traces may not deviate by more than a predetermined amount (e.g., 4 μm per cm) even after multiple thermal cycles (e.g., five thermal cycles to 250° C.). The reference point to determine deviation or misalignment can be determined by the defined geometries dictated by shadow, photolithographic, and/or other mask(s). Related art backplanes including polymer substrates, which can also include thin film conductors, dielectrics, and semiconductors, cannot be fabricated within these tolerances, and this limitation has limited large scale adoption of large are, low cost backplanes.

Different backplanes comprised of different combinations of substrates and patterned or otherwise defined electronic, insulating, and/or semiconducting structures can exhibit different amounts of substrate drift, which can make them more or less useful and play a role in navigating the tradeoff between feature sizes on a backplane and size of the backplane itself. For example, if substrate drift is higher, but the feature sizes are much larger, misalignment of multiple layers at distances across a large area has less relative effect, and it may still be possible to build functional devices. However, if, for example, two patterned semiconductors are each less than 40 microns in diameter, but separated 10 cm apart across the backplane, it becomes very difficult for both of these structures to be aligned relative to other masks. In this case, the source and drain may align well with one of the patterned semiconductors leading to predictable performance of that component, but be so misaligned on the other one, that the semiconductor-based component does not function as desired or does not work at all.

In an embodiment, a backplane can have dimensional stability in that the substrate drift is such that resulting aligned components do not deviate more than 10 μm per cm from the as-defined geometries as dictated by the dimensions of the shadow, photolithographic, and/or other mask after five thermal cycles to at least 275° C. The “per cm” indicates distance from a defined reference point, such as a center point or other reference point for lithography steps; that is, a substrate drift of 10 μm per cm or less means that alignment does not deviate by more than 10 μm for each cm moved away from the reference point (e.g., no more than 20 μm at 2 cm away, etc.). In another embodiment, substrate drift is less than 10 μm per cm over at least 5 thermal cycles to at least 270° C. In another embodiment, substrate drift is less than 10 μm per cm over at least 5 thermal cycles to at least 250° C. In another embodiment, substrate drift is less than 10 μm per cm over at least 5 thermal cycles to at least 210° C. In another embodiment, substrate drift is less than 10 μm per cm over at least 5 thermal cycles to at least 200° C. In another embodiment, substrate drift is less than 10 μm per cm over at least 5 thermal cycles to at least 150° C.

In a further embodiment, substrate drift is less than 4 μm per cm over at least 5 thermal cycles to at least 275° C. In another embodiment, substrate drift is less than 4 μm per cm over at least 5 thermal cycles to at least 270° C. In another embodiment, substrate drift is less than 4 μm per cm over at least 5 thermal cycles to at least 250° C. In another embodiment, substrate drift is less than 4 μm per cm over at least 5 thermal cycles to at least 210° C. In another embodiment, substrate drift is less than 4 μm per cm over at least 5 thermal cycles to at least 200° C. In another embodiment, substrate drift is less than 4 μm per cm over at least 5 thermal cycles to at least 150° C.

Substrate drift, or the displacement of a patterned feature in relation of a fixed point on top of a substrate due to a change in the surface of the substrate, can be caused due to thermal cycling to a certain temperature and/or due to exposure to chemicals such as acids, bases, and solvents. This can occur when photolithography, shadow-masking, and/or other techniques are used to micro-fabricate devices on a substrate. The importance of this parameter when choosing a substrate for flexible electronics fabrication becomes apparent when the device includes several layers of conductors, dielectrics, and/or semiconductors that have to be aligned consecutively. As previously mentioned, when the features to be fabricated are large, the misalignment of multiple layers at distance across a large area has less relative effect. However, when the device features are small themselves but positioned very far away, aligning them can be difficult or not possible if the substrate drifts more than the size of said features. For example, if a substrate having a contact pattern with a size of 10×10 microns has a substrate drift of 5 microns per cm, then when the next layer (e.g., dielectric), is aligned, only the features inside of a 2 cm radius would fall inside the layer already patterned. This becomes critical when the goal is fabrication in large area substrates because if the substrate drift is very low, that radius (usable area) can become as large as needed.

One of the most straightforward techniques to measure substrate drift can include depositing a layer of metal on top of the substrate to be measured. The metal layer can then be patterned with alignment marks in the form of a cross that can serve as a reference point in the x- and y-axis. Several marks can be repeated in the area to be measured. Then, the substrate can be subjected to the conditions in which the amount of substrate drift is to be tested (e.g., five thermal cycles of 5 minutes each at 250° C.). After, photoresist can be spun on top and baked. When aligning the next layer, the cross in the reference point should align correctly within the aligner tolerances. The aligning marks parallel in the x-axis should align correctly on the y-axis and move slightly in the x-axis, and the same is true for the marks in the y-axis, though the displacement will be on the x-axis. Once exposed and developed, the displacement can be measured in both the x- and y-axis and then divided by the distance between where the measured mark is and the reference point selected in the first step. This can give the amount of microns (per cm) the substrate drifts from the original position after the external stimulus occurs.

The multifunctional thiol monomers can include, for example, at least one of the following: trimethylolpropane tris(3-mercaptopropionate); trimethylolpropane tris(2-mercaptoacetate); pentaerythritol tetrakis(2-mercaptoacetate); pentaerythritol tetrakis(3-mercaptopropionate); 2,2′-(ethylenedioxy)diethanethiol; 1,3-Propanedithiol; 1,2-ethanedithiol; 1,4-butanedithiol; tris[2-(3-mercaptopropionyloxy)ethyl] isocyanurate; 3,4-ethylenedioxythiophene; 1,10-decanedithiol; tricyclo[5.2.1.02,6]decanedithiol; Benzene-1,2-dithiol; and trithiocyanuric acid. These are provided by way of example and should not be construed as limiting.

The multifunctional co-monomers can include, for example, at least one of the following: 1,3,5-triallyl-1,3,5-triazine-2,4,6(1H,3H,5H)-trione; tricyclo[5.2.1.02,6]decanedimethanol diacrylate; divinyl benzene; diallyl bisphenol A (diacetate ether); diallyl terephthalate; diallyl phthalate; diallyl maleate; trimethylolpropane diallyl ether; ethylene glycol dicyclopentenyl ether acrylate; diallyl carbonate; diallyl urea; 1,6-hexanediol diacrylate; cinnamyl cinnamate; vinyl cinnamate; allyl cinnamate; allyl acrylate; crotyl acrylate; cinnamyl methacrylate; trivinylcyclohexane; 1,4-cyclohexanedimethanol divinyl ether; poly(ethylene glycol) diacrylate; tricyclodecane dimethanol diacrylate; bisphenol A ethoxylate diarylate; tris[2-(acryloyloxy ethyl)] isocyanurate; trimethylolpropane triacrylate; pentaethrytolpropane tetraacrylate; dipentaethrytolpropane penta-/hexa-acrylate; poly(ethylene glycol) dimethacrylate; dimethanol dimethacrylate; bisphenol A ethoxylate dimetharylate; trimethylolpropane trimethacrylate; pentaethrytolpropane tetramethacrylate; bisphenol A diglycidyl Ether; neopentyl glycol diglycidyl ether; tris(2,3-epoxypropyl) isocyanurate; trimethylolpropane triglycidyl ether i. 1,1′-(methylenedi-4,1-phenylene)bismaleimide; 1,6-di(maleimido)hexane; 1,4-di(maleimido)butane; N,N′-(1,3-phenylene)dimaleimide; isophorone diisocyanate; xylylene diisocyanate; tolylene diisocyanate; 1,4-diisocyanatobutane, 1,6-diisocyanatohexane, 1,8-diisocyanatooctane; vinyl norbornene; dicyclopentadiene; and ethylidene norbornene. These are provided by way of example and should not be construed as limiting.

The small molecule additives can include, for example, at least one of the following: an acetophenone (e.g., 2,2-dimethoxyphenyl-2-acetophenone); a benzyl compound; a benzoin compound (e.g., benzoin methyl ether); a benzophenone (e.g., diphenyl ketone); a quinone (e.g., camphorquinone); a thioxanthone (e.g., 10-methylphenothiazine); azobisisobutyronitrile; benzoyl peroxide; and hydrogen peroxide. These are provided by way of example and should not be construed as limiting.

In one embodiment, a pre-thermoset mixture can include 42% of the multifunctional thiol monomer pentaerythritol tetrakis(3-mercaptopropionate) copolymerized with a stoichiometric equivalent 58% of the multifunctional co-monomer epoxide bisphenol A diglycidyl ether. In a further embodiment, the copolymerization reaction can be catalyzed. For example, the copolymerization reaction can be catalyzed by the addition of 1.5 wt % of triethylamine as an anionic polymerization catalyst.

In one embodiment, a pre-thermoset mixture can include 57% of the multifunctional thiol monomer trimethylolpropane tris(3-mercaptopropionate) copolymerized with a stoichiometric equivalent 43% of the multifunctional co-monomer alkene 1,4-cyclohexanedimethanol divinyl ether. In a further embodiment, the copolymerization reaction can be catalyzed. For example, the copolymerization reaction can be catalyzed by the addition of 1.5 wt % 2,2-dimethoxy-2-phenylacetophenone as a radical polymerization initiator.

In one embodiment, a method of using a backplane can include providing the backplane as described herein, and using the backplane for its intended purpose, which can include any of the many applications discussed herein.

In many embodiments, a method of fabricating a backplane can include fabricating a thermoset polymer as described herein as a substrate. The method can further include disposing additional structures on the substrate. The thermoset polymer can be fabricated by curing a pre-thermoset mixture, wherein the mixture is as described herein. The method can further include polymerizing the mixture using a reservoir (e.g., a pressurized reservoir). The mixture can be cured and/or cast using at least one of the following apparatuses: an oven; a slot die coater; a rod coater; a blade coater; a spin coater; and a reaction injection mold. The thermoset polymer can be used as a substrate that can be inserted into traditional semiconductor fabrication process equipment.

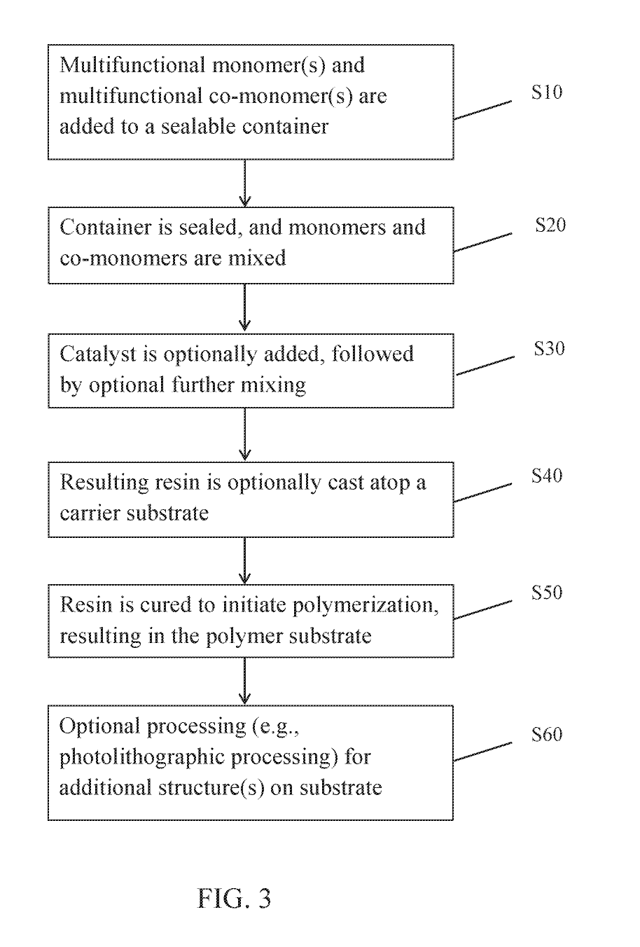

FIG. 3 shows a flow diagram of a method of fabricating a backplane according to an exemplary embodiment. Referring to FIG. 3, one or more types of multifunctional monomers and one or more types of multifunctional co-monomers can be added to a sealable container (S10). The container can be sealed and the monomers and co-monomers can be mixed (S20). For example, the mixing can be done using a rotary mixer, though embodiments are not limited thereto. Optionally, a catalyst can be added, followed by optional further mixing (S30). For example, such optional further mixing can be done using a rotary mixer, though embodiments are not limited thereto. The catalyst can be, for example, an anionic polymerization catalyst (e.g., triethylamine) or a radical polymerization initiator (e.g., 2,2-dimethoxy-2-phenylacetophenone), though embodiments are not limited thereto. Optionally, the resulting resin (whether catalyst was used or not) can be cast atop a carrier substrate (S40). The carrier substrate can be, for example, a wafer (e.g., a silicon wafer) or a glass substrate, though embodiments are not limited thereto. The resin can be cast atop the carrier substrate using, for example, one or more of the following techniques, though embodiments are not limited thereto: a slot die coater; a rod coater; a blade coater; or a spin coater. The resin (whether cast atop a carrier substrate or not) can be cured to initiate or continue polymerization, resulting in the thermoset polymer substrate (S50). The curing can be performed by, for example, introducing the resin into an oven (e.g., a curing oven) and baking for a period of time, though embodiments are not limited thereto. By way of example, the curing can be performed in a curing oven at a temperature of at least 65° C. for a period of time of at least one hour. Optionally, further processing (e.g., photolithographic processing) can be performed to form one or more additional structures on the polymer substrate (S60). Such additional structures are depicted in FIGS. 1 and 2 by reference numerals 150 and 250, respectively.

The substrate of the backplane of the subject invention is advantageously suitable for additional structures (e.g., multiple layers or multilayer devices) to be fabricated on it using traditional semiconductor processes (e.g., semiconductor photolithography). The substrate can enable multilayer microfabrication of electronic backplanes due to the use of pristine (low surface roughness), uniform (consistent thickness) polymers. The polymer can include, for example, at least one multifunctional thiol monomer, copolymerized with one or more reactive co-monomers via a thiol click chemical reaction. The materials can be polymerized using a reservoir (e.g., a pressurized reservoir), and the reservoir can feed into at least one curing and/or casting apparatus. Examples of curing and/or casting apparatuses include, but are not limited to, ovens, slot die coaters, rod coaters, blade coaters, spin coaters, and reaction injection molds. The final substrate can be removed and inserted into traditional semiconductor fabrication process equipment for steps including, but not limited to, variable temperature atomic layer deposition (ALD), variable temperature plasma enhanced chemical vapor deposition (PECVD), and metallization (e.g., via evaporation or sputtering).

In one embodiment, the polymer can be bonded on a carrier substrate. The carrier substrate can include, for example, a wafer (e.g., a silicon wafer) or a glass panel, though embodiments are not limited thereto. Once on the carrier substrate, the polymer can be processed in commercial silicon, panel, or other increasingly large area fabrication machines. At the end of the processing, the polymer can be separated from the carrier wafer or panel by any suitable means known in the art, and it can then be used as a flexible substrate for a backplane.

The backplane fabrication can include processes with multiple layers of photolithography performed on a substrate. Substrates of the subject invention allow for these processes to be performed. Low-cure-stress, thermoset networks permit the alignment of multiple masks/layers on the substrate for shadow-masking and photolithography processes. The polymer network can always be in the same state when aligning occurs, fixating the features and permitting several layers of materials to be deposited.

Embodiments of the subject invention can allow for device stacks with multiple (e.g., 2, 5, 10, 15, or more) layers that can be aligned with sub-micron scale precision. The limit on the alignment of the substrate of the subject invention may be proportional to the distance between crosslinks. Thus, backplanes of the subject invention include a substrate compatible with the smallest photolithography techniques used today to achieve dimensionally stable feature sizes below 500 nm, below 100 nm, below 50 nm, at or below 22 nm, at or below 14 nm, at or below 7 nm, and possible as low as a few nm.

The polymers of the substrate of the backplane can work at any temperature up to the decomposition temperature. Because the glass transition temperature is not the limit, as would otherwise be expected, this allows for a higher range of temperatures and more materials that can be used. In one embodiment, materials used for the backplane are thermally stable indefinitely at 270° C., and able to be processed for short periods of time (e.g., 30 minutes consecutively) above that temperature, for example up to 350° C.

The thermoset polymers according to the subject invention are also resistant to many chemicals used for photolithography, including but not limited to hydrofluoric acid (HF), buffered oxide etch (BOE), sodium hydroxide (NaOH), potassium hydroxide (KOH), acetone, and methyl isobutyl ketone (MiBK).

In one embodiment, one or more semiconductors can be deposited on the substrate. The semiconductors can include, for example, amorphous oxide semiconductors (e.g., IGZO). The semiconductors can be deposited via, for example, chemical vapor deposition (CVD) or another deposition technique at high temperature. This can result in better electronic properties, including but not limited to mobility and threshold voltage, when used in electronic devices such as diodes, capacitors, transistors, and resistors. All of these components can be included on an electronic backplane of the subject invention. The polymers of the subject invention can also be annealed at temperatures ranging from 180° C. to 310° C. to increase reliability and electronic and chemical properties. The annealing can be performed for a period of time of, for example, up to 3 hours.

Additional structures that can be disposed on the substrate can include contacts for source, drain, and gate electrodes. Materials for these structures can include, for example, metals, transparent conductive oxides, and polymer conductors, though embodiments are not limited thereto. Polymers, ceramics, and their composites can be used for gate dielectric materials and inter-layer dielectrics.

In one embodiment, the thermoset polymer substrate of the backplane can be suitable for deposition of materials at temperatures ranging from 0° C. to 310° C., including but not limited to nano crystalline silicon and poly crystalline silicon. The backplane can be a non-pick-and-place-based, flexible, electronics backplane that enables a mobility of greater than 10 cm²/V-s (square centimeter per Volt per second). The backplane can enable a mobility of greater than, for example, 40 cm²/V-s, 100 cm²/V-s, 200 cm²/V-s, or 500 cm²/V-s.

The polymers for the substrate of the backplane in the subjection invention can advantageously exhibit dimensional stability and thermal stability. Dimensional stability in the case of polymeric substrates refers to the ability of the substrate to prevent or attenuate drift in the bulk network through various external stimuli cycles, including, but not limited to, thermal cycling, elastic deformation, and other factors. Thermal stability in the case of polymeric substrates refers to the temperature range available for processing materials atop the substrate, including deposition methods such as sputtering and evaporation, annealing recipes for inducing crystallinity in these layers, and any other mechanism requiring the substrate to be exposed to elevated temperature. Thermal stability can be evaluated as either a specific temperature required for 1% or 5% of the material mass to be lost or as the onset temperature of thermal dissociation, where the material begins to lose mass quicker than the previous temperature range.

With regard to dimensional stability, the principle behind the thiol “click” reaction is the byproduct-free, step-growth mechanism of reaction propagation during curing of the resin. By creating a very large number of nucleation sites simultaneously or nearly simultaneously in the monomer solution during polymerization, these types of “click” reactions delay the gelation of the network such that cure stress is dramatically reduced, if not wholly eliminated, during the polymerization reaction. This type of polymerization, which can be referred to as a step-growth mechanism, can be created via free-radical polymerization, anionic or cationic initiation via the Michael addition, or regular nucleophilic addition enabled by elevated temperatures. With any of these polymerization mechanisms, the resultant network can be formed with little to no cure stress, leading to highly uniform networks.

The polymer networks of the subject invention have little of the internal stressors that lead to dramatic relaxation of the polymer substrate once the material is cycled through any transition temperature, as exampled by the glass transition temperature. With this property, photolithographic alignment of fine features is possible over large area substrates through the multiple processing steps required for flexible electronic manufacturing, including but not limited to thin film transistor (TFT) fabrication and organic light emitting diode (OLED) fabrication.

Similar to the relaxation of internal cure stresses built into the network, the use of thermosetting materials as dimensionally stable substrates can instill chemically-formed, permanent netpoints into the material system of the substrate. These permanent netpoints, hereinafter referred to as crosslinks, can serve as the driving factor to drive the substrates described herein back to the same or close-to-the-same internal structure through the multiple thermal cycles required in the photolithographic fabrication of flexible electronics. In thermoplastic polymers, the netpoints (crosslinks) are physical in nature, including physical entanglements below transition temperatures and packing-based entanglements such as crystallites below phase-change temperatures (such as Tm), and do not provide the same consistency in reformation from thermal cycle to subsequent thermal cycle. Fabrication of flexible electronics atop related art thermoplastic substrates, even at temperatures below transition and phase-change temperatures, therefore may not allow for reliable and reproducible alignment over subsequent photolithographic steps requiring thermal cycling or cycling other environmental stimuli.

Electronic backplanes of the subject invention, though, include a polymer for the substrate, wherein the polymer is a thermoset material with chemical netpoints (crosslinks) that utilize a low-cure-stress polymerization mechanism, leading to a substrate with high dimensional stability through thermal and other stimuli cycling. The polymerization mechanism also has as an initial fabrication state that cures the final polymer in a low-internal-stress architecture that does not disrupt, or only negligibly disrupts, surface morphology when polymer chain relaxation is performed (e.g., transition through the glass transition).

With regard to thermal stability, the subject invention utilizes a polymeric system with a thermal stability allowing for <1% mass loss indefinitely at temperatures between 250° C. and 275° C., and <5% mass loss at temperatures between 275° C. to 375° C. in inert atmospheres for periods of time ranging up to 30 minutes. This can be accomplished by using the materials and proportions thereof as described herein.

Electronic backplanes of the subject invention can be utilized in several applications, including but not limited to displays, X-ray detectors, temperature sensors, pressure sensors, sensors for health fitness monitoring, implantable sensors, sensors for use in extreme environments (e.g., down-hole or underwater), and other applications where controlling flexible, bendable electronics is needed or desired.

Though related art backplanes for electronics use attempt to use materials with a low coefficient of thermal expansion (CTE) and/or a high Tg as a flexible substrate, the polymers described herein are surprisingly effective and advantageous as a flexible substrate for an electronics backplane even though the CTE can be relatively high and the Tg can be relatively low.

The polymers described herein can advantageously be used as a substrate of a backplane for any of the following applications, though embodiments are not limited thereto: ultra-light, transparent, flexible active matrix displays; ultra-light, non-transparent, flexible active matrix displays; ultra-light, flexible passive matrix displays; ultra-light, transparent, flexible, wearable sensors; ultra-light, non-transparent, flexible, wearable sensors; ultra-light, flexible lightning applications; ultra-light, transparent and flexible liquid crystal displays (LCDs); ultra-light, flexible radiation detectors; ultra-light, flexible barcode devices; ultra-light, flexible labeling devices; ultra-light, flexible tracking devices; ultra-light, flexible wearable sensors; and ultra-light, flexible health monitoring of civil structures, people, food, drinks, or other goods.

The subject invention includes, but is not limited to, the following exemplified embodiments.

### Embodiment 1

A backplane, comprising:

a substrate comprising a thermoset polymer.

### Embodiment 2

The backplane according to embodiment 1, wherein the thermoset polymer is prepared by curing a pre-thermoset mixture,

wherein the pre-thermoset mixture includes one or more first multifunctional monomers and one or more second multifunctional monomers.

### Embodiment 3

The backplane according to embodiment 2, wherein the pre-thermoset mixture further includes at least one small molecule additive.

### Embodiment 4

The backplane according to any of embodiments 2-3, wherein the first multifunctional monomers are multifunctional thiol monomers.

### Embodiment 5

The backplane according to embodiment 4, wherein the second multifunctional monomers are co-monomers that have a functionality compatible with a thiol monomer to result in a thiol click chemistry reaction taking place.

### Embodiment 6

The backplane according to any of embodiments 2-5, wherein the pre-thermoset mixture comprises from about 25 wt % to about 65 wt % of one or more multifunctional thiol monomers and from about 25 wt % to about 65 wt % of one or more multifunctional co-monomers.

### Embodiment 7

The backplane according to embodiment 6, wherein the pre-thermoset mixture further comprises from about 0.001 wt % to about 10 wt % of small molecule additives.

### Embodiment 8

The backplane according to any of embodiments 2-7, wherein the first multifunctional monomers include at least one of the following: trimethylolpropane tris(3-mercaptopropionate); trimethylolpropane tris(2-mercaptoacetate); pentaerythritol tetrakis(2-mercaptoacetate); pentaerythritol tetrakis(3-mercaptopropionate); 2,2′-(ethylenedioxy)diethanethiol; 1,3-Propanedithiol; 1,2-ethanedithiol; 1,4-butanedithiol; tris[2-(3-mercaptopropionyloxy)ethyl] isocyanurate; 3,4-ethylenedioxythiophene; 1,10-decanedithiol; tricyclo[5.2.1.02,6]decanedithiol; Benzene-1,2-dithiol; and trithiocyanuric acid.

### Embodiment 9

The backplane according to any of embodiments 2-8, wherein the second multifunctional monomers include at least one of the following: 1,3,5-triallyl-1,3,5-triazine-2,4,6(1H,3H,5H)-trione; tricyclo[5.2.1.02,6]decanedimethanol diacrylate; divinyl benzene; diallyl bisphenol A (diacetate ether); diallyl terephthalate; diallyl phthalate; diallyl maleate; trimethylolpropane diallyl ether; ethylene glycol dicyclopentenyl ether acrylate; diallyl carbonate; diallyl urea; 1,6-hexanediol diacrylate; cinnamyl cinnamate; vinyl cinnamate; allyl cinnamate; allyl acrylate; crotyl acrylate; cinnamyl methacrylate; trivinylcyclohexane; 1,4-cyclohexanedimethanol divinyl ether; poly(ethylene glycol) diacrylate; tricyclodecane dimethanol diacrylate; bisphenol A ethoxylate diarylate; tris[2-(acryloyloxy ethyl)] isocyanurate; trimethylolpropane triacrylate; pentaethrytolpropane tetraacrylate; dipentaethrytolpropane penta-/hexa-acrylate; poly(ethylene glycol) dimethacrylate; dimethanol dimethacrylate; bisphenol A ethoxylate dimetharylate; trimethylolpropane trimethacrylate; pentaethrytolpropane tetramethacrylate; bisphenol A diglycidyl Ether; neopentyl glycol diglycidyl ether; tris(2,3-epoxypropyl) isocyanurate; trimethylolpropane triglycidyl ether i. 1,1′-(methylenedi-4,1-phenylene)bismaleimide; 1,6-di(maleimido)hexane; 1,4-di(maleimido)butane; N,N′-(1,3-phenylene)dimaleimide; isophorone diisocyanate; xylylene diisocyanate; tolylene diisocyanate; 1,4-diisocyanatobutane, 1,6-diisocyanatohexane, 1,8-diisocyanatooctane; vinyl norbornene; dicyclopentadiene; and ethylidene norbornene.

### Embodiment 10

The backplane according to any of embodiments 3-9, wherein the small molecule additives include at least one of the following: an acetophenone (e.g., 2,2-dimethoxyphenyl-2-acetophenone); a benzyl compound; a benzoin compound (e.g., benzoin methyl ether); a benzophenone (e.g., diphenyl ketone); a quinone (e.g., camphorquinone); a thioxanthone (e.g., 10-methylphenothiazine); azobisisobutyronitrile; benzoyl peroxide; and hydrogen peroxide.

### Embodiment 11

The backplane according to any of embodiments 1-10, wherein the thermoset polymer has a substrate drift of less than 3.5 μm/cm at a temperature of at least 275° C.

### Embodiment 12

The backplane according to any of embodiments 1-11, wherein the substrate is flexible.

### Embodiment 13

The backplane according to any of embodiments 1-12, further comprising at least one semiconductor structure on the substrate.

### Embodiment 14

The backplane according to embodiment 13, wherein the semiconductor structure includes an amorphous oxide semiconductor (e.g., IGZO).

### Embodiment 15

The backplane according to any of embodiments 13-14, wherein the semiconductor structure includes a silicon (Si) semiconductor.

### Embodiment 16

The backplane according to any of embodiments 13-15, wherein the semiconductor structure includes a poly-Si semiconductor.

### Embodiment 17

The backplane according to any of embodiments 13-16, wherein the semiconductor structure includes an organic semiconductor (e.g., an organic thin film transistor).

### Embodiment 18

The backplane according to any of embodiments 13-17, wherein the semiconductor structure includes a diode.

### Embodiment 19

The backplane according to any of embodiments 13-18, wherein the semiconductor structure includes a transistor.

### Embodiment 20

The backplane according to any of embodiments 13-19, wherein the semiconductor structure includes a capacitor.

### Embodiment 21

The backplane according to any of embodiments 13-20, wherein the semiconductor structure includes a resistor.

### Embodiment 22

The backplane according to any of embodiments 1-21, wherein the thermoset polymer is capable of being processed at a temperature higher than the glass transition temperature of the thermoset polymer.

### Embodiment 23

The backplane according to any of embodiments 2-22, wherein the thermoset polymer comprises the one or more first multifunctional monomers and the one or more second multifunctional monomers.

### Embodiment 24

The backplane according to any of embodiments 1-23, wherein the thermoset polymer is cross-linked.

### Embodiment 25

The backplane according to any of embodiments 1-24, wherein the backplane is capable of enabling a mobility of at least 10 cm²/V-s.

### Embodiment 26

The backplane according to any of embodiments 1-24, wherein the backplane is capable of enabling a mobility of at least 40 cm²/V-s.

### Embodiment 27

The backplane according to any of embodiments 1-24, wherein the backplane is capable of enabling a mobility of at least 100 cm²/V-s.

### Embodiment 28

The backplane according to any of embodiments 1-24, wherein the backplane is capable of enabling a mobility of at least 200 cm²/V-s.

### Embodiment 29

The backplane according to any of embodiments 1-24, wherein the backplane is capable of enabling a mobility of at least 500 cm²/V-s.

### Embodiment 30

The backplane according to any of embodiments 1-29, further comprising at least one thin film conductive layer disposed on the substrate.

### Embodiment 31

The backplane according to any of embodiments 1-30, further comprising at least one thin film semiconducting layer disposed on the substrate.

### Embodiment 32

A method of using a backplane, the method comprising:

providing the backplane according to any of embodiments 1-31; and

using the backplane for its intended purpose based on a desired application.

### Embodiment 33

A method of fabricating a backplane, the method comprising:

preparing a pre-thermoset mixture; and

curing the pre-thermoset mixture to form a thermoset polymer as a substrate of the backplane,

wherein the pre-thermoset mixture includes one or more first multifunctional monomers and one or more second multifunctional monomers.

### Embodiment 34

The method according to embodiment 33, wherein the pre-thermoset mixture further includes one or more small molecule additive.

### Embodiment 35

The method according to any of embodiments 33-34, wherein the first multifunctional monomers are multifunctional thiol monomers.

### Embodiment 36

The method according to embodiment 35, wherein the second multifunctional monomers are co-monomers that have a functionality compatible with a thiol monomer to result in a thiol click chemistry reaction taking place.

### Embodiment 37

The method according to any of embodiments 33-36, further comprising polymerizing the one or more first multifunctional monomers and the one or more second multifunctional monomers.

### Embodiment 38

The method according to embodiment 37, wherein the polymerization is a click chemistry reaction.

### Embodiment 39

The method according to embodiment 38, wherein the polymerization is a thiol click chemistry reaction.

### Embodiment 40

The method according to any of embodiments 33-39, wherein the pre-thermoset mixture comprises from about 25 wt % to about 65 wt % of one or more multifunctional thiol monomers and from about 25 wt % to about 65 wt % of one or more multifunctional co-monomers.

### Embodiment 41

The method according to embodiment 40, wherein the pre-thermoset mixture further comprises from about 0.001 wt % to about 10 wt % of small molecule additives.

### Embodiment 42

The method according to any of embodiments 33-41, wherein the first multifunctional monomers include at least one of the following: trimethylolpropane tris(3-mercaptopropionate); trimethylolpropane tris(2-mercaptoacetate); pentaerythritol tetrakis(2-mercaptoacetate); pentaerythritol tetrakis(3-mercaptopropionate); 2,2′-(ethylenedioxy)diethanethiol; 1,3-Propanedithiol; 1,2-ethanedithiol; 1,4-butanedithiol; tris[2-(3-mercaptopropionyloxy)ethyl] isocyanurate; 3,4-ethylenedioxythiophene; 1,10-decanedithiol; tricyclo[5.2.1.02,6]decanedithiol; Benzene-1,2-dithiol; and trithiocyanuric acid.

### Embodiment 43

The method according to any of embodiments 33-42, wherein the second multifunctional monomers include at least one of the following: 1,3,5-triallyl-1,3,5-triazine-2,4,6(1H,3H,5H)-trione; tricyclo[5.2.1.02,6]decanedimethanol diacrylate; divinyl benzene; diallyl bisphenol A (diacetate ether); diallyl terephthalate; diallyl phthalate; diallyl maleate; trimethylolpropane diallyl ether; ethylene glycol dicyclopentenyl ether acrylate; diallyl carbonate; diallyl urea; 1,6-hexanediol diacrylate; cinnamyl cinnamate; vinyl cinnamate; allyl cinnamate; allyl acrylate; crotyl acrylate; cinnamyl methacrylate; trivinylcyclohexane; 1,4-cyclohexanedimethanol divinyl ether; poly(ethylene glycol) diacrylate; tricyclodecane dimethanol diacrylate; bisphenol A ethoxylate diarylate; tris[2-(acryloyloxy ethyl)] isocyanurate; trimethylolpropane triacrylate; pentaethrytolpropane tetraacrylate; dipentaethrytolpropane penta-/hexa-acrylate; poly(ethylene glycol) dimethacrylate; dimethanol dimethacrylate; bisphenol A ethoxylate dimetharylate; trimethylolpropane trimethacrylate; pentaethrytolpropane tetramethacrylate; bisphenol A diglycidyl Ether; neopentyl glycol diglycidyl ether; tris(2,3-epoxypropyl) isocyanurate; trimethylolpropane triglycidyl ether i. 1,1′-(methylenedi-4,1-phenylene)bismaleimide; 1,6-di(maleimido)hexane; 1,4-di(maleimido)butane; N,N′-(1,3-phenylene)dimaleimide; isophorone diisocyanate; xylylene diisocyanate; tolylene diisocyanate; 1,4-diisocyanatobutane, 1,6-diisocyanatohexane, 1,8-diisocyanatooctane; vinyl norbornene; dicyclopentadiene; and ethylidene norbornene.

### Embodiment 44

The method according to any of embodiments 33-43 wherein the small molecule additives include at least one of the following: an acetophenone (e.g., 2,2-dimethoxyphenyl-2-acetophenone); a benzyl compound; a benzoin compound (e.g., benzoin methyl ether); a benzophenone (e.g., diphenyl ketone); a quinone (e.g., camphorquinone); a thioxanthone (e.g., 10-methylphenothiazine); azobisisobutyronitrile; benzoyl peroxide; and hydrogen peroxide.

### Embodiment 45

The method according to any of embodiments 33-44, wherein the thermoset polymer has a substrate drift of less than 3.5 μm/cm at a temperature of at least 275° C.

### Embodiment 46

The method according to any of embodiments 33-45, wherein the substrate is flexible.

### Embodiment 47

The method according to any of embodiments 33-48, wherein the thermoset polymer is capable of being processed at a temperature higher than the glass transition temperature of the thermoset polymer.

### Embodiment 48

The method according to any of embodiments 33-47, wherein the backplane is capable of enabling a mobility of at least 10 cm²/V-s.

### Embodiment 49

The method according to any of embodiments 33-47, wherein the backplane is capable of enabling a mobility of at least 40 cm²/V-s.

### Embodiment 50

The method according to any of embodiments 33-47, wherein the backplane is capable of enabling a mobility of at least 100 cm²/V-s.

### Embodiment 51

The method according to any of embodiments 33-47, wherein the backplane is capable of enabling a mobility of at least 200 cm²/V-s.

### Embodiment 52

The method according to any of embodiments 33-47, wherein the backplane is capable of enabling a mobility of at least 500 cm²/V-s.

### Embodiment 53

The method according to any of embodiments 33-52, wherein the pre-thermoset mixture is polymerized in a pressurized reservoir.

### Embodiment 54

The method according to any of embodiments 33-53, further comprising forming at least one semiconductor structure on the substrate.

### Embodiment 55

The method according to embodiment 54, wherein the semiconductor structure includes an amorphous oxide semiconductor (e.g., IGZO).

### Embodiment 56

The method according to any of embodiments 54-55, wherein the semiconductor structure includes a silicon (Si) semiconductor.

### Embodiment 57

The method according to any of embodiments 54-56, wherein the semiconductor structure includes a poly-Si semiconductor.

### Embodiment 58

The method according to any of embodiments 54-57, wherein the semiconductor structure includes an organic semiconductor (e.g., an organic thin film transistor).

### Embodiment 59

The method according to any of embodiments 54-58, wherein the semiconductor structure includes a diode.

### Embodiment 60

The method according to any of embodiments 54-59, wherein the semiconductor structure includes a transistor.

### Embodiment 61

The method according to any of embodiments 54-60, wherein the semiconductor structure includes a capacitor.

### Embodiment 62

The method according to any of embodiments 54-61, wherein the semiconductor structure includes a resistor.

### Embodiment 63

The method according to any of embodiments 33-62, wherein the pre-thermoset mixture is cured and/or cast using at least one of the following apparatuses: an oven; a slot die coater; a rod coater; a blade coater; a spin coater; and a reaction injection mold.

### Embodiment 64

The method according to any of embodiments 33-63, further comprising inserting the substrate into semiconductor fabrication process equipment.

### Embodiment 65

The method according to embodiment 64, wherein, while in the semiconductor fabrication process equipment, at least one of the following processes is performed on the substrate: variable temperature atomic layer deposition (ALD); variable temperature plasma enhanced chemical vapor deposition (PECVD); and metallization (e.g., via evaporation or sputtering).

### Embodiment 66

The method according to any of embodiments 33-65, further comprising bonding the thermoset polymer substrate to a carrier substrate.

### Embodiment 67

The method according to embodiment 66, wherein the carrier substrate is a wafer (e.g., a silicon wafer) or a glass panel.

### Embodiment 68

The method according to any of embodiments 66-67, wherein, once bonded to the carrier substrate, the thermoset polymer substrate is processed in a large area fabrication machine.

### Embodiment 69

The method according to embodiment 68, further comprising separating the thermoset polymer substrate from the carrier substrate after it is processed in the large area fabrication machine.

### Embodiment 70

The method according to any of embodiments 33-69, further comprising, after curing the pre-thermoset mixture, thermally cycling the backplane to a temperature of at least 150° C. (i.e., heating to 150° C. and allowing to cool is one thermal cycle to 150° C.).

### Embodiment 71

The method according to any of embodiments 33-70, further comprising, after curing the pre-thermoset mixture, thermally cycling the backplane to a temperature of at least 180° C.

### Embodiment 72

The method according to any of embodiments 33-71, further comprising, after curing the pre-thermoset mixture, thermally cycling the backplane to a temperature of at least 210° C.

### Embodiment 73

The method according to any of embodiments 33-72, further comprising, after curing the pre-thermoset mixture, thermally cycling the backplane to a temperature of at least 240° C.

### Embodiment 74

The method according to any of embodiments 33-73, further comprising, after curing the pre-thermoset mixture, thermally cycling the backplane to a temperature of at least 270° C.

### Embodiment 75

The method according to any of embodiments 33-74, further comprising, after curing the pre-thermoset mixture, thermally cycling the backplane to a temperature of at least 300° C.

### Embodiment 76

The method according to any of embodiments 33-75, further comprising, after curing the pre-thermoset mixture, thermally cycling the backplane to a temperature of at least 275° C. at least five times.

### Embodiment 77

The method according to any of embodiments 33-76, further disposing the pre-thermoset mixture onto a prefabricated semiconductor device and performing at least one of the following processes on the substrate of the backplane: variable temperature atomic layer deposition (ALD); variable temperature plasma enhanced chemical vapor deposition (PECVD); metallization via evaporation; and metallization via sputtering.

### Embodiment 78

The method according to any of embodiments 33-77, further comprising forming at least one thin film conductive layer on the substrate.

### Embodiment 79

The method according to any of embodiments 33-78, further comprising forming at least one thin film semiconducting layer on the substrate.

### Embodiment 80

The backplane according to embodiment 31 or the method according to embodiment 79, wherein the thin film semiconducting layer comprises at least one of the following: an amorphous oxide semiconductor; a silicon (Si) semiconductor; a poly-Si semiconductor; and an organic semiconductor.

### Embodiment 81

The backplane or method according to embodiment 80, wherein the amorphous oxide semiconductor is zinc oxide or indium gallium zinc oxide, and wherein the organic semiconductor is pentacene, dinaphtho[2,3-b:29,39-f]thieno[3,2-b]thiophene, or another thiophene.

### Embodiment 82

The backplane or method according to any of embodiments 31 and 79-81, wherein the backplane comprises at least one of the following: at least one diode; at least one transistor, at least one capacitor; and at least one resistor.

### Embodiment 83

The backplane or method according to any of embodiments 30-31 and 78-82, wherein the thin film conductive layer comprises at least one of the following: gold; platinum; palladium; tungsten; silver; copper; aluminum; nickel; titanium; chromium; iridium; an oxide of aluminum; an oxide of nickel; an oxide of titanium; an oxide of chromium; an oxide of iridium; doped ultrananocrystalline diamond; graphene platelets; reduced graphene oxide; carbon nanotubes; indium tin oxide; metal nanowires; and titanium nitride.

### Embodiment 84

The backplane or method according to any of embodiments 30-31 and 78-83, wherein the thin film conductive layer comprises silver nanowires.

### Embodiment 85

The backplane or method according to any of embodiments 30-31 and 78-84, wherein the backplane further comprises a dielectric layer comprising at least one of the following materials: hafnium oxide; parylene; parylene-C; silicon nitride; silicon carbide; and insulating ultrananocrystalline diamond.

### Embodiment 86

The backplane or method according to any of embodiments 1-85, wherein the backplane has a substrate drift of less than 10 μm per cm over at least 5 thermal cycles to at least 275° C.

### Embodiment 87

The backplane or method according to any of embodiments 1-85, wherein the backplane has a substrate drift of less than 10 μm per cm over at least 5 thermal cycles to at least 270° C.

### Embodiment 88

The backplane or method according to any of embodiments 1-85, wherein the backplane has a substrate drift of less than 10 μm per cm over at least 5 thermal cycles to at least 250° C.

### Embodiment 89

The backplane or method according to any of embodiments 1-85, wherein the backplane has a substrate drift of less than 10 μm per cm over at least 5 thermal cycles to at least 210° C.

### Embodiment 90

The backplane or method according to any of embodiments 1-85, wherein the backplane has a substrate drift of less than 10 μm per cm over at least 5 thermal cycles to at least 200° C.

### Embodiment 91

The backplane or method according to any of embodiments 1-85, wherein the backplane has a substrate drift of less than 10 μm per cm over at least 5 thermal cycles to at least 150° C.

### Embodiment 92

The backplane or method according to any of embodiments 1-85, wherein the backplane has a substrate drift of less than 4 μm per cm over at least 5 thermal cycles to at least 275° C.

### Embodiment 93

The backplane or method according to any of embodiments 1-85, wherein the backplane has a substrate drift of less than 4 μm per cm over at least 5 thermal cycles to at least 270° C.

### Embodiment 94

The backplane or method according to any of embodiments 1-85, wherein the backplane has a substrate drift of less than 4 μm per cm over at least 5 thermal cycles to at least 250° C.

### Embodiment 95

The backplane or method according to any of embodiments 1-85, wherein the backplane has a substrate drift of less than 4 μm per cm over at least 5 thermal cycles to at least 210° C.

### Embodiment 96

The backplane or method according to any of embodiments 1-85, wherein the backplane has a substrate drift of less than 4 μm per cm over at least 5 thermal cycles to at least 200° C.

### Embodiment 97

The backplane or method according to any of embodiments 1-85, wherein the backplane has a substrate drift of less than 4 μm per cm over at least 5 thermal cycles to at least 150° C.

A greater understanding of the present invention and of its many advantages may be had from the following examples, given by way of illustration. The following examples are illustrative of some of the methods, applications, embodiments and variants of the present invention. They are, of course, not to be considered as limiting the invention. Numerous changes and modifications can be made with respect to the invention.

### Example 1

To a sealable container was added pentaerythritol tetrakis(3-mercaptopropionate) (1 mol eq.) and bisphenol A diglycidyl ether (1.5 mol eq.), and the container was sealed. The sealed container was placed into a rotary mixer (FlackTek Speedmixer™) and vortexed at 2750 rotations per minute (rpm) for 5 minutes. The container was removed from the mixer, opened, and 1.5 wt % of the catalyst triethylamine was pipetted dropwise into the mixed resin at room temperature (about 25° C.). The container was again sealed, placed into the rotary mixer and vortexed at 2750 rpm for an additional 5 minutes. The resin mixture was cast atop a carrier substrate using a casting technique. The cast resin was introduced to a curing oven at 65° C. to initiate the polymerization and baked for at least 1 hour, giving the polymer substrate. After the polymerization, the polymer substrate (either on the carrier substrate or separated therefrom) was ready for photolithographic processing.

### Example 2

To a sealable container was added trimethylolpropane tris(3-mercaptopropionate) and 1,4-cyclohexanedimethanol divinyl ether, and the container was sealed. The sealed container was placed into a rotary mixer (FlackTek Speedmixer™) and vortexed at 2750 rotations per minute (rpm) for 5 minutes. The container was removed from the mixer, opened, and 1.5 wt % of the catalyst 2,2-dimethoxy-2-phenylacetophenone was pipetted dropwise into the mixed resin at room temperature (about 25° C.). The container was again sealed, placed into the rotary mixer and vortexed at 2750 rpm for an additional 5 minutes. The resin mixture was cast atop a carrier substrate using a casting technique. The cast resin was introduced to a curing oven at 65° C. to initiate the polymerization and baked for at least 1 hour, giving the polymer substrate. After the polymerization, the polymer substrate (either on the carrier substrate or separated therefrom) was ready for photolithographic processing.

It should be understood that the examples and embodiments described herein are for illustrative purposes only and that various modifications or changes in light thereof will be suggested to persons skilled in the art and are to be included within the spirit and purview of this application.

All patents, patent applications, provisional applications, and publications referred to or cited herein are incorporated by reference in their entirety, including all figures and tables, to the extent they are not inconsistent with the explicit teachings of this specification.

1. A backplane, comprising:
a substrate comprising a thermoset polymer,
wherein the thermoset polymer is prepared by curing a pre-thermoset mixture,
wherein the pre-thermoset mixture comprises from about 25 wt % to about 65 wt % of one or more multifunctional thiol monomers and from about 25 wt % to about 65 wt % of one or more multifunctional co-monomers.

2. The backplane according to claim 1, further comprising:
a thin film conductive layer disposed on the substrate;
a thin film semiconducting layer disposed on the substrate; and
a thin film dielectric layer disposed on the substrate.

3. The backplane according to claim 1, wherein the pre-thermoset mixture further comprises from about 0.001 wt % to about 10 wt % of small molecule additives.

4. The backplane according to claim 3, wherein the small molecule additives include at least one of the following: an acetophenone; a benzyl compound; a benzoin compound; a benzophenone; a quinone; a thioxanthone; azobisisobutyronitrile; benzoyl peroxide; and hydrogen peroxide.

5. The backplane according to claim 1, wherein the multifunctional thiol monomers include at least one of the following: trimethylolpropane tris(3-mercaptopropionate); trimethylolpropane tris(2-mercaptoacetate); pentaerythritol tetrakis(2-mercaptoacetate); pentaerythritol tetrakis(3-mercaptopropionate); 2,2′-(ethylenedioxy)diethanethiol; 1,3-Propanedithiol; 1,2-ethanedithiol; 1,4-butanedithiol; tris[2-(3-mercaptopropionyloxy)ethyl]isocyanurate; 1,10-decanedithiol; tricyclo[5.2.1.02,6]decanedithiol; Benzene-1,2-dithiol; and trithiocyanuric acid, and
wherein the multifunctional co-monomers include at least one of the following: 1,3,5-triallyl-1,3,5-triazine-2,4,6(1H,3H,5H)-trione; tricyclo[5.2.1.02,6]decanedimethanol diacrylate; divinyl benzene; diallyl bisphenol A (diacetate ether); diallyl terephthalate; diallyl phthalate; diallyl maleate; trimethylolpropane diallyl ether; ethylene glycol dicyclopentenyl ether acrylate; diallyl carbonate; diallyl urea; 1,6-hexanediol diacrylate; cinnamyl cinnamate; vinyl cinnamate; allyl cinnamate; allyl acrylate; crotyl acrylate; cinnamyl methacrylate; trivinylcyclohexane; 1,4-cyclohexanedimethanol divinyl ether; poly(ethylene glycol) diacrylate; tricyclodecane dimethanol diacrylate; bisphenol A ethoxylate diarylate; tris[2-(acryloyloxy ethyl)] isocyanurate; trimethylolpropane triacrylate; pentaethrytolpropane tetraacrylate; dipentaethrytolpropane penta-/hexa-acrylate; poly(ethylene glycol) dimethacrylate; dimethanol dimethacrylate; bisphenol A ethoxylate dimetharylate; trimethylolpropane trimethacrylate; pentaethrytolpropane tetramethacrylate; bisphenol A diglycidyl Ether; neopentyl glycol diglycidyl ether; tris(2,3-epoxypropyl) isocyanurate; trimethylolpropane triglycidyl ether i. 1,1′-(methylenedi-4,1-phenylene)bismaleimide; 1,6-di(maleimido)hexane; 1,4-di(maleimido)butane; N,N′-(1,3-phenylene)dimaleimide; isophorone diisocyanate; xylylene diisocyanate; tolylene diisocyanate; 1,4-diisocyanatobutane, 1,6-diisocyanatohexane, 1,8-diisocyanatooctane; vinyl norbornene; dicyclopentadiene; and ethylidene norbornene.

6. The backplane according to claim 1, wherein the multifunctional thiol monomers include at least one of the following: trimethylolpropane tris(3-mercaptopropionate); trimethylolpropane tris(2-mercaptoacetate); pentaerythritol tetrakis(2-mercaptoacetate); pentaerythritol tetrakis(3-mercaptopropionate); 2,2′-(ethylenedioxy)diethanethiol; 1,3-Propanedithiol; 1,2-ethanedithiol; 1,4-butanedithiol; tris[2-(3-mercaptopropionyloxy)ethyl]isocyanurate; 1,10-decanedithiol; tricyclo[5.2.1.02,6]decanedithiol; Benzene-1,2-dithiol; and trithiocyanuric acid.

7. The backplane according to claim 1, wherein the multifunctional co-monomers include at least one of the following: 1,3,5-triallyl-1,3,5-triazine-2,4,6(1H,3H,5H)-trione; tricyclo[5.2.1.02,6]decanedimethanol diacrylate; divinyl benzene; diallyl bisphenol A (diacetate ether); diallyl terephthalate; diallyl phthalate; diallyl maleate; trimethylolpropane diallyl ether; ethylene glycol dicyclopentenyl ether acrylate; diallyl carbonate; diallyl urea; 1,6-hexanediol diacrylate; cinnamyl cinnamate; vinyl cinnamate; allyl cinnamate; allyl acrylate; crotyl acrylate; cinnamyl methacrylate; trivinylcyclohexane; 1,4-cyclohexanedimethanol divinyl ether; poly(ethylene glycol) diacrylate; tricyclodecane dimethanol diacrylate; bisphenol A ethoxylate diarylate; tris[2-(acryloyloxy ethyl)] isocyanurate; trimethylolpropane triacrylate; pentaethrytolpropane tetraacrylate; dipentaethrytolpropane penta-/hexa-acrylate; poly(ethylene glycol) dimethacrylate; dimethanol dimethacrylate; bisphenol A ethoxylate dimetharylate; trimethylolpropane trimethacrylate; pentaethrytolpropane tetramethacrylate; bisphenol A diglycidyl Ether; neopentyl glycol diglycidyl ether; tris(2,3-epoxypropyl) isocyanurate; trimethylolpropane triglycidyl ether i. 1,1′-(methylenedi-4,1-phenylene)bismaleimide; 1,6-di(maleimido)hexane; 1,4-di(maleimido)butane; N,N′-(1,3-phenylene)dimaleimide; isophorone diisocyanate; xylylene diisocyanate; tolylene diisocyanate; 1,4-diisocyanatobutane, 1,6-diisocyanatohexane, 1,8-diisocyanatooctane; vinyl norbornene; dicyclopentadiene; and ethylidene norbornene.

8. The backplane according to claim 1, wherein the substrate is flexible, and
wherein the thermoset polymer is capable of being processed at a temperature higher than the glass transition temperature of the thermoset polymer.

9. (canceled)

10. The backplane according to claim 2, wherein the thin film semiconducting layer comprises at least one of the following: an amorphous oxide semiconductor; a silicon (Si) semiconductor; a poly-Si semiconductor; and an organic semiconductor, and
wherein the amorphous oxide semiconductor is zinc oxide or indium gallium zinc oxide, and wherein the organic semiconductor is pentacene, dinaphtho[2,3-b:29,39-f]thieno[3,2-b]thiophene, or another thiophene.

11-15. (canceled)

16. A method of fabricating a backplane, the method comprising:
preparing a pre-thermoset mixture; and
curing the pre-thermoset mixture to form a thermoset polymer as a substrate of the backplane,
wherein the pre-thermoset mixture comprises from about 25 wt % to about 65 wt % of one or more multifunctional thiol monomers and from about 25 wt % to about 65 wt % of one or more multifunctional co-monomers.

17. The method according to claim 16, further comprising:
forming a thin film conductive layer on the substrate;
forming a thin film semiconducting layer on the substrate; and
forming a thin film dielectric layer on the substrate.

18. The method according to claim 16, wherein the pre-thermoset mixture further comprises from about 0.001 wt % to about 10 wt % of small molecule additives.

19. The method according to claim 18, wherein the small molecule additives include at least one of the following: an acetophenone; a benzyl compound; a benzoin compound; a benzophenone; a quinone; a thioxanthone; azobisisobutyronitrile; benzoyl peroxide; and hydrogen peroxide.

20. The method according to claim 16, wherein the multifunctional thiol monomers include at least one of the following: trimethylolpropane tris(3-mercaptopropionate); trimethylolpropane tris(2-mercaptoacetate); pentaerythritol tetrakis(2-mercaptoacetate); pentaerythritol tetrakis(3-mercaptopropionate); 2,2′-(ethylenedioxy)diethanethiol; 1,3-Propanedithiol; 1,2-ethanedithiol; 1,4-butanedithiol; tris[2-(3-mercaptopropionyloxy)ethyl]isocyanurate; 1,10-decanedithiol; tricyclo[5.2.1.02,6]decanedithiol; Benzene-1,2-dithiol; and trithiocyanuric acid, and
wherein the multifunctional co-monomers include at least one of the following: 1,3,5-triallyl-1,3,5-triazine-2,4,6 (1H,3H,5H)-trione; tricyclo[5.2.1.02,6]decanedimethanol diacrylate; divinyl benzene; diallyl bisphenol A (diacetate ether); diallyl terephthalate; diallyl phthalate; diallyl maleate; trimethylolpropane diallyl ether; ethylene glycol dicyclopentenyl ether acrylate; diallyl carbonate; diallyl urea; 1,6-hexanediol diacrylate; cinnamyl cinnamate; vinyl cinnamate; allyl cinnamate; allyl acrylate; crotyl acrylate; cinnamyl methacrylate; trivinylcyclohexane; 1,4-cyclohexanedimethanol divinyl ether; poly(ethylene glycol) diacrylate; tricyclodecane dimethanol diacrylate; bisphenol A ethoxylate diarylate; tris[2-(acryloyloxy ethyl)] isocyanurate; trimethylolpropane triacrylate; pentaethrytolpropane tetraacrylate; dipentaethrytolpropane penta-/hexa-acrylate; poly(ethylene glycol) dimethacrylate; dimethanol dimethacrylate; bisphenol A ethoxylate dimetharylate; trimethylolpropane trimethacrylate; pentaethrytolpropane tetramethacrylate; bisphenol A diglycidyl Ether; neopentyl glycol diglycidyl ether; tris(2,3-epoxypropyl) isocyanurate; trimethylolpropane triglycidyl ether i. 1,1′-(methylenedi-4,1-phenylene)bismaleimide; 1,6-di(maleimido)hexane; 1,4-di(maleimido)butane; N,N′-(1,3-phenylene)dimaleimide; isophorone diisocyanate; xylylene diisocyanate; tolylene diisocyanate; 1,4-diisocyanatobutane, 1,6-diisocyanatohexane, 1,8-diisocyanatooctane; vinyl norbornene; dicyclopentadiene; and ethylidene norbornene.

21. The method according to claim 16, wherein the multifunctional thiol monomers include at least one of the following: trimethylolpropane tris(3-mercaptopropionate); trimethylolpropane tris(2-mercaptoacetate); pentaerythritol tetrakis(2-mercaptoacetate); pentaerythritol tetrakis(3-mercaptopropionate); 2,2′-(ethylenedioxy)diethanethiol; 1,3-Propanedithiol; 1,2-ethanedithiol; 1,4-butanedithiol; tris[2-(3-mercaptopropionyloxy)ethyl]isocyanurate; 1,10-decanedithiol; tricyclo[5.2.1.02,6]decanedithiol; Benzene-1,2-dithiol; and trithiocyanuric acid.

22. The method according to claim 16, wherein the multifunctional co-monomers include at least one of the following: 1,3,5-triallyl-1,3,5-triazine-2,4,6 (1H,3H,5H)-trione; tricyclo[5.2.1.02,6]decanedimethanol diacrylate; divinyl benzene; diallyl bisphenol A (diacetate ether); diallyl terephthalate; diallyl phthalate; diallyl maleate; trimethylolpropane diallyl ether; ethylene glycol dicyclopentenyl ether acrylate; diallyl carbonate; diallyl urea; 1,6-hexanediol diacrylate; cinnamyl cinnamate; vinyl cinnamate; allyl cinnamate; allyl acrylate; crotyl acrylate; cinnamyl methacrylate; trivinylcyclohexane; 1,4-cyclohexanedimethanol divinyl ether; poly(ethylene glycol) diacrylate; tricyclodecane dimethanol diacrylate; bisphenol A ethoxylate diarylate; tris[2-(acryloyloxy ethyl)] isocyanurate; trimethylolpropane triacrylate; pentaethrytolpropane tetraacrylate; dipentaethrytolpropane penta-/hexa-acrylate; poly(ethylene glycol) dimethacrylate; dimethanol dimethacrylate; bisphenol A ethoxylate dimetharylate; trimethylolpropane trimethacrylate; pentaethrytolpropane tetramethacrylate; bisphenol A diglycidyl Ether; neopentyl glycol diglycidyl ether; tris(2,3-epoxypropyl) isocyanurate; trimethylolpropane triglycidyl ether i. 1,1′-(methylenedi-4,1-phenylene)bismaleimide; 1,6-di(maleimido)hexane; 1,4-di(maleimido)butane; N,N′-(1,3-phenylene)dimaleimide; isophorone diisocyanate; xylylene diisocyanate; tolylene diisocyanate; 1,4-diisocyanatobutane, 1,6-diisocyanatohexane, 1,8-diisocyanatooctane; vinyl norbornene; dicyclopentadiene; and ethylidene norbornene.

23. The method according to claim 16, wherein the substrate is flexible, and
wherein the thermoset polymer is capable of being processed at a temperature higher than the glass transition temperature of the thermoset polymer.

24. (canceled)

25. The method according to claim 17, wherein the thin film semiconducting layer comprises at least one of the following: an amorphous oxide semiconductor; a silicon (Si) semiconductor; a poly-Si semiconductor; and an organic semiconductor, and
wherein the amorphous oxide semiconductor is zinc oxide or indium gallium zinc oxide, and wherein the organic semiconductor is pentacene, dinaphtho[2,3-b:29,39-f]thieno[3,2-b]thiophene, or another thiophene.

26-32. (canceled)

33. The method according to claim 16, further comprising, after curing the pre-thermoset mixture, thermally cycling the backplane to a temperature of at least 150° C.

34-37. (canceled)

38. The method according to claim 16, further comprising, after curing the pre-thermoset mixture, thermally cycling the backplane to a temperature of at least 250° C.

39-40. (canceled)
